(19) United States
(12) Patent Application Publication
(10) Pub. No.: US 2018/0102451 A1
(43) Pub. Date: Apr. 12, 2018

(54) METHOD FOR PRODUCING A THIN FILM SOLAR CELL MODULE AND THIN FILM SOLAR CELL MODULE

(71) Applicant: BEIJING APOLLO DING RONG SOLAR TECHNOLOGY CO. LTD., Beijing (CN)

(72) Inventors: Johan MATHIASSON, Uppsala (SE); Markus VOGL, Leipzig (DE); Juhan LUNDBERG, Sollentuna (SE); Olle LUNDBERG, Uppsala (SE); Patrick MENDE, Leipzig (DE)

(73) Assignee: BEIJING APOLLO DING RONG SOLAR TECHNOLOGY CO. LTD., Beijing (CN)

(21) Appl. No.: 15/830,332

(22) Filed: Dec. 4, 2017

Related U.S. Application Data
(62) Division of application No. 15/033,143, filed on Apr. 29, 2016.

(30) Foreign Application Priority Data
Oct. 30, 2013 (DE) 102013111981.6

(51) Int. Cl. H01L 31/0465; H01L 31/18; H01L 31/0224; H01L 31/046; H01L 31/20

(52) U.S. Cl. CPC H01L 31/0465; Y02E 10/52; H01L 31/1884; H01L 31/18; H01L 31/022441; Y02P 70/521; H01L 31/046; H01L 31/206; H01L 31/022466; H01L 31/022433

(57) ABSTRACT

The invention relates to a method for producing a thin film solar cell module and thin film solar cell module thus produces. The method comprises the steps of forming a multi-layer structure (100) of multiple electrically interconnected thin film solar cells (1) on a substrate (2), the multi-layer structure comprising a back contact layer (10), a photovoltaic active layer (11), and a front contact layer (13); and forming a conductive grid (3) underneath or onto the front contact layer by depositing a conductive material through a mask (4) before or after forming the front contact layer (13), by moving the substrate (2) and the mask (4) with respect to a deposition source (5) of the conductive material.

### CROSS REFERENCE TO RELATED APPLICATIONS

This application is a Divisional of U.S. application Ser. No. 15/033,143 filed Apr. 29, 2016, which is a National Stage of International Application No. PCT/EP2014/073244, filed on Oct. 29, 2014, which claims priority from German Patent Application No. 10 2013 111 981.6, filed on Oct. 30, 2013, the contents of all of which are incorporated by reference herein in their entirety.

### DESCRIPTION

The invention relates to a method for producing a thin film solar cell module and thin film solar cell module.

A thin film solar cell module usually comprises a multi-layer structure of multiple electrically interconnected thin film solar cells on a substrate, the multi-layer structure comprising a back contact layer, a photovoltaic active layer, and a front contact layer. The photovoltaic active layer or photovoltaic absorber may in particular be an absorber made of copper indium gallium (di)selenide (CIGS). The front contact layer has to be transparent in order to allow incoming light to reach the absorber and is therefore made of a transparent oxide, for example ZnO. In order to increase the lateral conductivity of the front contact layer, a metallic collector grid may be placed onto the transparent oxide. US 2010 243046 A discloses a chalcogenide based photovoltaic device having a chalcogenide absorber, a buffer layer, a transparent conductive oxide layer, and a metallic collector grid.

The collector grid is often made of a material that conducts electricity well such as Cu or Al, though other metals may be used, as described in US 2010 243046 A. Such a metal collector grid shadows the active layer of the solar cell, thus reducing its efficiency. The grid line width may be reduced in order to reduce the shadowing effect. However, this will also reduce the conductance of the grid lines.

It is an object of the present invention to provide for a solar cell module having an improved conductivity of the front side contact while at the same time having high conversion efficiency, and a method for producing such a solar cell.

The object is achieved by this invention by providing a method with the features of claim 1 and a thin film solar cell module with the features of claim 7. Advantageous embodiments of the invention are subject of the sub-claims.

The invention is based on the idea of providing the usually transparent front contact layer with a conductive grid, whereby the grid lines of the conductive grid are designed in such a way as to function as light collecting structures. This means that light incident on a grid line is reflected in such a way that a further internal reflection of the reflected light at a module interface directs it back to the module surface, preferable to a position on the module surface where there are no grid lines. In order to achieve this, a conductive material is deposited through a mask by moving the substrate, on which the multiple electrically interconnected thin film solar cells are produced, and the mask with respect to a deposition source of the conductive material. The mask is stationary with the substrate and preferably in contact with the substrate.

The conductive grid may be produced on top of the front contact layer, i.e. on a surface of the front contact layer facing away from the substrate, or it may be deposited underneath the front contact layer, i.e. on a surface of the front contact layer facing towards the substrate. In both cases, it is preferable that the conductive grid is in electrical contact with the front contact layer in order to increase its conductivity.

Using this method, the manufactured thin film solar cell module comprising a multi-layer structure of multiple electrically interconnected thin film solar cells on the substrate, further comprises a conductive grid underneath or on the front contact layer. The conductive grid is made of a conductive material and has at least one elongated grid line or conductive line, which in a cross-section plane perpendicular to its longitudinal direction and perpendicular to the surface of the substrate has a surface contour with a top section and side sections flanking the top section. The conductive line needs also to be reflective, at least for incident light for which the solar cell module is designed. Due to the movement of the substrate relative to the deposition source while at the same time the mask is in a fixed position with respect to the substrate, the cross-section surface contour of the conductive line has a shape such that any tangent on one or both of the side sections together with a layer surface of said multi-layer structure underneath the conductive grid create a maximum angle (a), which is smaller than 80°, smaller than 70°, or smaller than 60°.

Usually, when producing a conductive grid, the emphasis is on trying to achieve grid lines with vertical or almost vertical edges. That is, the tangent at the leading edge (also called left side sections or left slope) and/or the tail edge (also called right side sections or right slope) of the surface contour of the grid line is made to be at a 90° angle with the surface of the layer underneath the conductive grid. By, instead of such vertical sides, achieving a sloping side section on one or both sides of the top section, having a tangential angle of less than 80°, 70°, or 60°, the corresponding side section can provide a reflecting surface for the incoming light such that the reflected light may be reflected back onto the module surface at an internal interface of the module and reach the photovoltaic active layer after these multiple reflections. Advantageously, the mask, the deposition source and the movement of the substrate and mask with respect to the deposition source are designed such as to assure that said maximum angle on one or both side sections is smaller than 50°, smaller than 40°, or smaller than 30°.

As mentioned before, the multi-layer structure comprises a back contact layer, a photovoltaic active layer, and a front contact layer. The front contact layer is the layer that the incident light impinges on and should therefore be transparent. Preferably it is made of a transparent conductive oxide (TCO), such as a metal oxide. The back contact layer does not have to be transparent;

therefore it may be made of a metal such as molybdenum. The photovoltaic active layer, sometimes also called the light collecting layer, between the front and back side contact layer preferably forms a PN-junction. It is preferably a chalcogenide absorber and may in particular be made of copper indium gallium (di)selenide (CIGS). Said multi-layer structure may be placed on the substrate with the back contact layer facing the substrate. The back contact layer is preferably placed directly on the substrate. In this case the substrate may be opaque or it may be transparent, for example made of glass. Alternatively, the multi-layer structure may be placed on the substrate with the front contact layer facing the substrate, which lay in this case be called a superstrate.

Herein, the layers of the solar cell module facing away from the light incident side are regarded as the bottom layers, such as the back contact layer, while the layers on which the incident light impinges first, such as the front contact layer, are regarded as the top layers. Accordingly, the top and bottom of each layer is defined as the side of the layer facing the light incident side of the module or opposite side. Since the conductive line or lines may be formed either on the top or on the bottom side of the front contact layer, the layer surface of said multi-layer structure underneath the conductive lines acting as a reference surface against which said angle of the tangent of the surface contour is measured, may be the front contact layer if the conductive lines are placed on top of the front contact layer, or the layer underneath the front contact layer in the case that the conductive lines are placed underneath the front contact layer, in particular the active layer or an optional buffer layer. According to some advantageous embodiments, there may be provided conductive lines on top of the front contact layer and further conductive lines underneath the front contact layer.

In a preferred embodiment, the conductive grid is deposited in the form of substantially parallel conductive lines. The conductive grid may have a first set of parallel conductive lines and a second set of parallel conductive lines set perpendicular to the first set. However, such a second set of conductive lines are not necessary in order to form the conductive grid.

In an advantageous embodiment, the conductive material is deposited through the mask having elongated openings oriented along a longitudinal direction. In other words, the mask has parallel slots oriented in the longitudinal direction. Such elongated openings lead to conductive lines being deposited onto the front contact layer or onto the layer below the front contact layer, which extend along the same longitudinal direction.

The deposition source is advantageously elongated along a deposition source axis. That means that it has an extension along the deposition source axis, which is larger than its extension perpendicular to that deposition source axis. The deposition source may in particular be made of multiple point sources distributed along that deposition source axis, for example of more than 10 or 15 such point sources. One example of such point sources is a wire feed evaporator, where a wire of the evaporation material is fed continuously to a ribbon shaped or boat shaped heater. Alternatively, the deposition source may be made of a line source extending along said deposition source axis.

The movement of the substrate and mask with relative to the deposition source is preferably directed perpendicular to such a deposition source axis such that by moving the substrate relative to the deposition source substantially all parts of the substrate will have passed under or over the deposition source.

The relative movement may be achieved by either moving the substrate and mask with respect to a stationary deposition source, by moving the deposition source with respect to a substrate held stationary, or by moving both the substrate and the deposition source. In all cases, the substrate may pass either over or under the deposition source, whereby under or over are defined in terms of how the deposition device is placed on the ground.

In a preferred embodiment, the substrate and the mask are moved under or over the deposition source in a direction parallel or perpendicular to the longitudinal direction of the elongated openings of the mask. This movement pertains to the relative movement of the substrate and mask with respect to the deposition source. When the movement is parallel to the longitudinal direction of the elongated openings, then the conductive lines that form due to the deposition through the mask are built up along their longitudinal direction or along their length. In other words, some or (depending on the size of the deposition source) all of the conductive lines are deposited at the same time, growing in length as the deposition process takes place. On the other hand, if the movement is perpendicular to the longitudinal direction of the elongated openings, then the conductive lines that form due to the deposition through the mask are deposited consecutively one after the other, as the deposition source moves from one opening of the mask to the other.

In an advantageous embodiment, the elongated openings of the mask have a width perpendicular to the longitudinal direction of less than 100 μm, or of between 30 μm and 70 μm. The depth of the opening, i.e. the length along which the width of the opening is constant and which is measured perpendicular to the substrate surface, lies preferably between 50 μm and 200 μm or between 50 μm and 150 μm, more preferably around 100 μm. Advantageously, the mask itself is much thicker, in order to obtain a rigid structure, while the opening having that opening width is placed directly on the substrate, the mask has a recess on the opposite side, which has a width of more than 0.5 mm or 1 mm. The depth of the mask opening mentioned above is therefore equal the thickness of the mask at the recess region.

In a preferred embodiment, said multi-layer structure is formed such that the interconnected thin film solar cells on said substrate are divided by dividing lines, whereby the conductive lines are formed such that they are parallel to the dividing lines. In this embodiment, the solar cells are in the form of narrow and long slabs, the photovoltaic active layers of which are separated from each other through the dividing lines and connected by the front and back contact layers in series. Each solar cell module may be made up of more than 50 or 100 slab solar cells, preferably of 150 slab solar cells.

The top section of the contour of the conductive line may form a plateau and be substantially flat. In an advantageous embodiment said top section and/or said one or both side sections are curved. Advantageously, said conductive line has a cross section substantially in the shape of a bell curve.

Alternatively or additionally, at least one of the side sections or a part of it is straight. Both side sections might each form a straight line. In this case, the conductive line may have a substantially v-shaped, triangular cross section. In other words, the two side sections consist of two slopes rising from the surface below the conductive line and meeting at a tip of the conductive line. Advantageously, if one or both side sections are a straight line, it or they may form an angle against the underlying surface, which has the above mentioned maximum values of 80°, 70°, 60°, 50°, 40°, or 30°. As explained further below, a sloping angle of 31° may correspond to a triangularly shaped cross-section of the conductive line having a height to width ratio of 3:10.

In a preferred embodiment, said conductive line has a width along said cross section of between 60 μm and 130 μm, or between 80 μm and 100 μm. The width is preferably referring to the full width at half maximum (FWHM).

In an advantageous embodiment, said conductive grid is a metal grid. I.e., the conductive lines may be formed of metal such as Aluminum, Silver or Copper.

In a preferred embodiment, the conductive grid consists of parallel elongated conductive lines oriented along said longitudinal direction. The conductive lines may be separated from each other by a gap of between 1 mm and 5 mm, preferably between 1.5 mm and 4 mm, more preferably between 2 mm and 3 mm. If the interconnected thin film solar cells on said substrate are divided by dividing lines, the conductive lines are advantageously substantially parallel to the dividing lines.

Some examples of embodiments of the invention will be explained in more detail in the following description with reference to the accompanying schematic drawings, wherein:

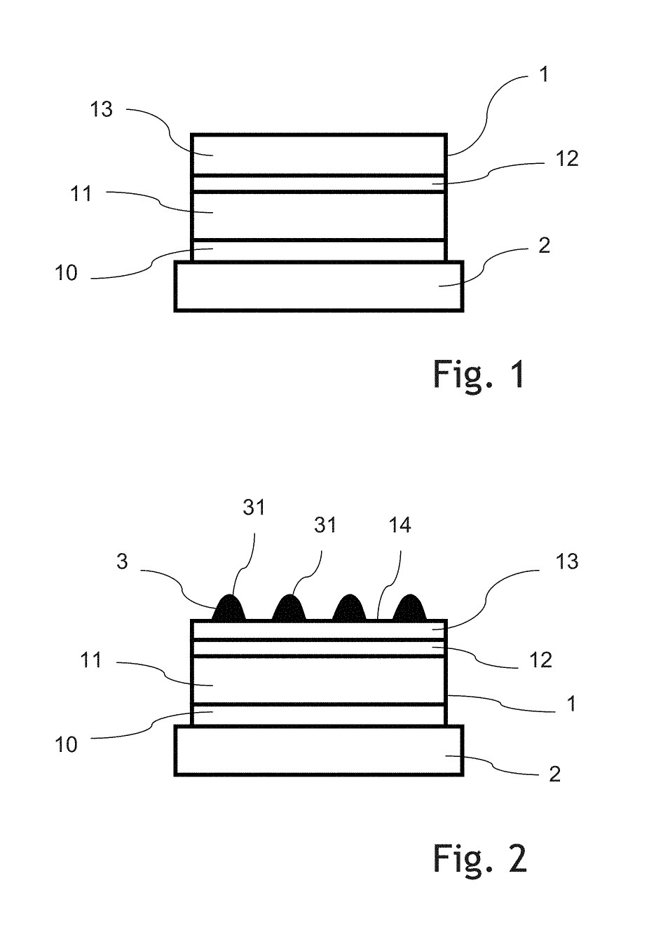

FIG. 1 shows the cross-section of a multi-layer structure of a thin film solar cell module;

FIG. 2 shows the cross-section of a multi-layer structure of a thin film solar cell module having a conductive grid;

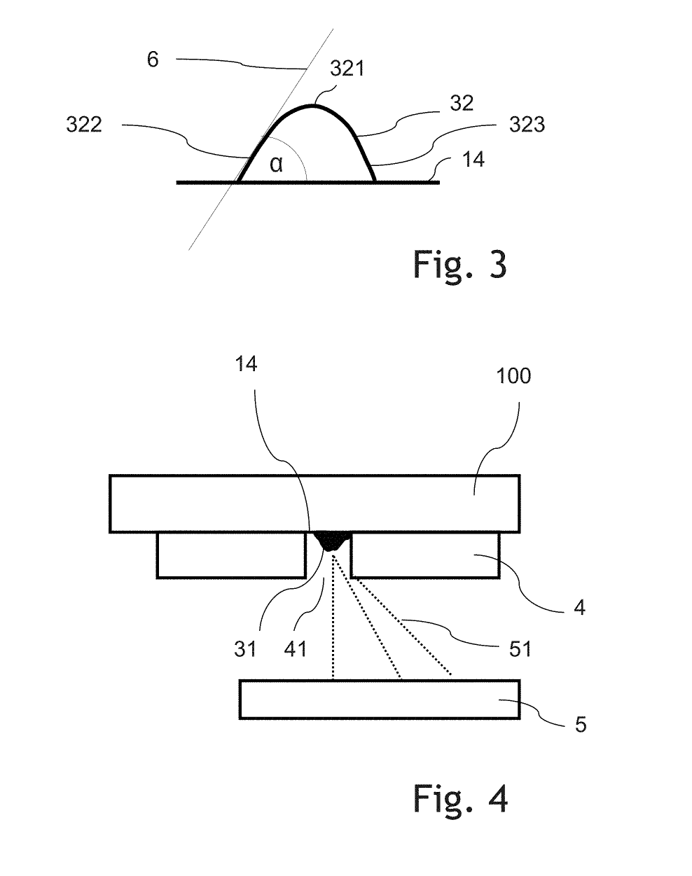

FIG. 3 shows a surface contour of a conductive line according to one embodiment;

FIG. 4 shows a schematic cross-sectional view on a setup for depositing a conductive line through a mask;

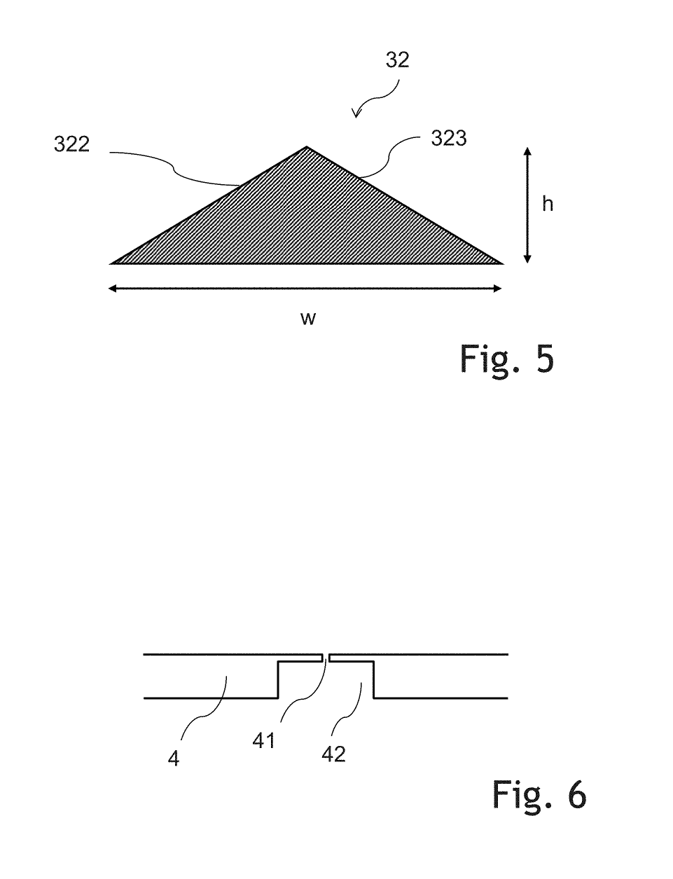

FIG. 5 shows a surface contour of a conductive line according to a further embodiment;

FIG. 6 shows the cross-section of a mask for depositing a conductive line;

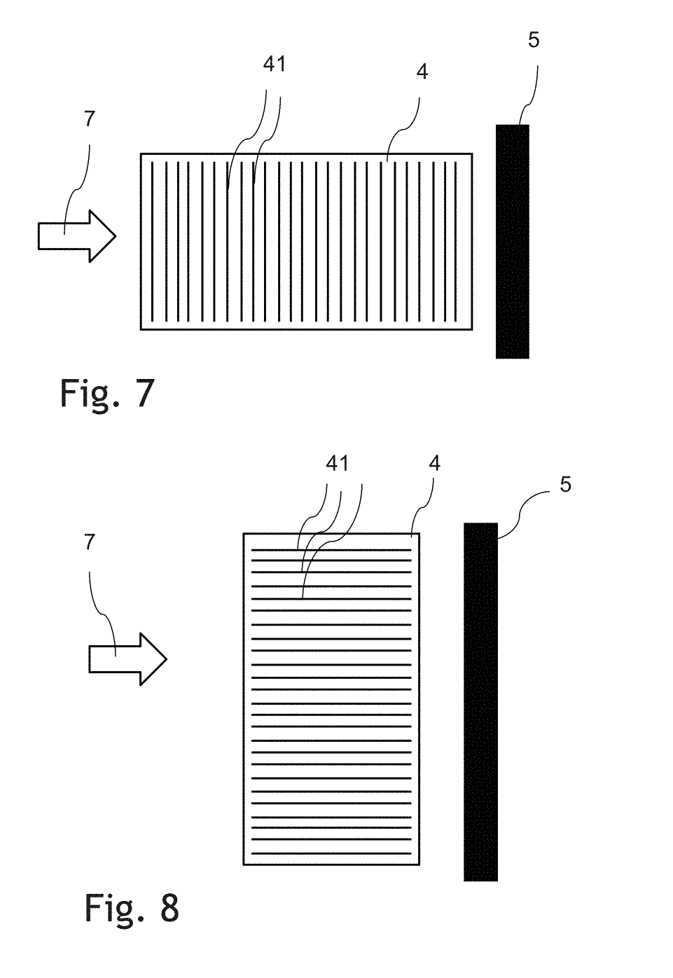

FIG. 7 shows a view onto a mask while the mask and substrate pass a deposition source according to one embodiment of a method for producing a thin film solar cell module;

FIG. 8 shows a view onto a mask while the mask and substrate pass a deposition source according to a different embodiment of a method for producing a thin film solar cell module;

FIG. 1 is a schematic cross-section of a multi-layer structure of a thin film solar cell 1. A substrate 2 is shown, on which the multi-layer structure is provided. The multi-layer structure comprises a back contact layer 10 placed on the substrate 2, a front contact layer 13 facing away from the substrate 2 and a photovoltaic active layer 11 sandwiched between the two contact layers 10, 13. There is a further buffer layer 12 on the photovoltaic active layer 11, which is optional.

FIG. 2 shows a similar structure as in FIG. 1 with the difference that this solar cell 1 comprises a conductive grid 3 having conductive grid lines 31, the cross-section of four of which can be seen in FIG. 2. Here, the conductive grid 3 is placed on a layer surface 14, which is a light incident surface of the front contact layer 13. In other embodiments not shown here, the conductive grid 3 may be placed underneath the front contact layer 13, such that the layer surface 14 may be an interface between the front contact layer 13 and the buffer layer 12 or between the front contact layer 13 and the photovoltaic active layer 11 in the case where there is no buffer layer 12.

The conductive lines 31 in FIG. 2 are shown with a curved surface contour 32, which is shown in more detail in FIG. 3. The contour 32 comprises a top section 321 flanked by two side sections 322, 323, namely a left slope 322 and a right slope 323. The contour 32 is symmetrical, so that the left slope 322 or left side section 322 is a mirror image of the right slope 323 or right side section 323. Tangents 6 of the side sections at a certain height therefore have the same but inverse angle with respect to the layer surface 14 on which the conductive line 3 is placed. One tangent 6 of the left side section 322 is shown in FIG. 3. The tangent 6 along the entire contour 32 has a maximum angle smaller or equal a, whereby a is 80° or less, depending on the embodiment.

Light incident perpendicular to the layer surface 14 and therefore perpendicular to the substrate (not shown in FIG. 3) onto the conductive line 3 will be reflected also perpendicular or nearly perpendicular back up, if it is incident on the top section of the contour 321. However, if the incident light hits either of the side sections 322, 323, it is reflected at an angle. When reaching an interface of the module from below, the reflected light will be reflected again, for example due to internal reflection, and impinge on the layer surface 14 at a position where there are no conductive lines 3.

FIG. 4 shows a setup for depositing the conductive line 3. The multi-layer structure 100 comprising the substrate 2 is covered by a mask 4, which has an opening 41 elongated in a direction perpendicular to the plane of the drawing. Only a section of the multi-layer structure 100 and the mask 4 are shown here, so that only one opening 41 is visible. A deposition source 5 such as an evaporator is placed below the multi-layer structure 100, on the side covered by the mask 4. The deposition source 5 is also elongated in the direction perpendicular to the plane of drawing and therefore parallel to the longitudinal direction of the opening 41. While the deposition source 5 is stationary, the multi-layer structure 100 together with the mask 4 are moved above the deposition layer 5, in the arrangement of FIG. 4 from left to right parallel to the drawing plane.

The deposition source 5 produces material beams 51 of the material to be deposited onto the layer surface 14 to form the conductive line 31. Different material beams 51 arrive at different angles through the opening 41 at the layer surface 14. During the movement of the multi-layer structure 100 over the deposition source 5, the conductive line 31 is being built up. Its form depends on the parameters of the deposition source 5 as well as on the aspect ratio of the opening 41 and the distance between the mask and the deposition source.

A contour 32 of a conductive line 3 having straight side sections 322, 323 is shown in FIG. 5. Here, the height of the conductive line 3 is defined as h, which is in the region of a few μm, preferably between 1 and 10 μm, while the width is defined as w. The ratio of height h to width w is preferably between 1:10 and 5:10, more preferably around 3:10. For a height of around 3 μm, this corresponds to a width of around 10 μm. In this special case, the width w is not defined as FWHM, but rather as the width of the base of the triangle making up the cross-section of the conductive line 3.

A cross-section of the mask 4 is shown in FIG. 6. As in FIG. 4, the mask 4 has an opening 41 elongated along a longitudinal direction running perpendicular to the plane of drawing. The mask 4 itself needs to have a minimum thickness in order to be robust and for easier handling. Therefore, in order to allow for a certain very small depth of the opening 41. There is a wider recess 42 provided behind the opening 41. Only the opening 41 will have an effect on the form and size of the resulting conductive line 3, while the recess 42 has a width and depth such that it does not affect the deposition process.

Two different deposition situations are shown schematically in FIGS. 7 and 8. They both show a bottom view onto a the mask 4 covering the multi-layer structure (not visible in FIGS. 7 and 8) such that the elongated openings 41 are visible. The arrow 7 shows the direction of movement of the substrate 2 and mask 4. On the right side, there is a schematic representation of a deposition source 5. In both cases, the length of the deposition source 5 perpendicular to the movement direction 7 is large enough to cover the entire dimension of the substrate 2 and mask 4 perpendicular to the movement direction, while the width of the deposition source 5, namely its extension along the movement direction 7 is narrow with respect to its length.

In FIG. 7, the substrate 2 and mask 4 are moved in a direction 7 perpendicular to the longitudinal direction of the elongated openings 41 in the mask 4. Therefore, due to the size and design of the deposition source 5, one conductive line 31 after the other is completed onto the multi-layer structure 100, while the substrate 2 and mask 4 move over the deposition source 5. The situation is different in FIG. 8, where the substrate 2 and mask 4 are moved in a direction 7 parallel to the longitudinal direction of the elongated openings 41 in the mask 4. Here, all conductive lines 31 are deposited at the same time, being built up along their length, while the substrate 2 and mask 4 move over the deposition source 5. In the case of FIG. 8 one can say that the material beams 51 having different angles with respect to each mask opening 41 are present for all openings 41 at all times during the deposition process, while in FIG. 7 the angles at which the material beams 51 arrive at each opening 41 changes with time as the mask 4 and the deposition source 5 are moved relative to each other.

### REFERENCE NUMBERS

1 thin film solar cell
10 back contact layer
11 photovoltaic active layer
12 buffer layer (optional)
13 front contact layer
14 layer surface
100 multi-layer structure
2 substrate
3 conductive grid
31 conductive (grid) line
32 surface contour
321 top section
322 left side sections (left slope)
323 right side sections (right slope)
4 mask
41 elongated opening
42 opening recess
5 deposition source
51 material beam
6 tangent
7 moving direction

1. Thin film solar cell module comprising a multi-layer structure of multiple electrically interconnected thin film solar cells (1) on a substrate (2), the multi-layer structure comprising a back contact layer (10), a photovoltaic active layer (11), a front contact layer (13), and a conductive grid (3) underneath or on the front contact layer (13) made of a conductive material, characterized by that an elongated conductive line (31) of said conductive grid (3) in a cross-section plane perpendicular to its longitudinal direction has a surface contour (32) having a top section (321) and two side sections (322, 323) flanking the top section (321), whereby any tangent (5) on one or both of the side sections (322, 323) together with a layer surface (14) of said multi-layer structure underneath the conductive grid (3) create a maximum angle (a), which is smaller than 80°, smaller than 70°, or smaller than 60°.

2. Thin film solar cell module according to claim 1, characterized by that said top section (321) and/or said one or both side sections (322, 323) are curved.

3. Thin film solar cell module according to claim 1, characterized by that said conductive line (31) has a cross section substantially in the shape of a bell curve.

4. Thin film solar cell module according to claim 1, characterized by that said conductive line (31) has a substantially v-shaped cross section.

5. Thin film solar cell module according to one of the claim 1, characterized by that said conductive line has a width along said cross section of between 60 μm and 130 μm, or between 80 μm and 100 μm.

6. Thin film solar cell module according to one of the claim 1, characterized by that said conductive grid (3) is a metal grid.

7. Thin film solar cell module according to one of the claim 1, characterized by that the conductive grid (3) consists of parallel elongated conductive lines (31) oriented along said longitudinal direction.

8. Thin film solar cell module according to claim 7, characterized by that the interconnected thin film solar cells on said substrate (2) are divided by dividing lines, whereby the conductive lines (31) are substantially parallel to the dividing lines.
